(19) United States
(12) Patent Application Publication
(10) Pub. No.: US 2016/0238661 A1
(43) Pub. Date: Aug. 18, 2016

(54) METHOD AND APPARATUS FOR DETERMINING THE STATE OF CHARGE OF A RECHARGEABLE BATTERY BY MEANS OF AN OPEN-CIRCUIT VOLTAGE CHARACTERISTIC CURVE OF THE RECHARGEABLE BATTERY

(71) Applicant: Dr. Ing. h.c. F. Porsche Aktiengesellschaft, Stuttgart (DE)

(72) Inventors: Ulrich Eger, Zaberfeld (DE); Markus Höppe, Altena (DE); Wolfgang Herdeg, Rutesheim (DE)

(21) Appl. No.: 15/042,896

(22) Filed: Feb. 12, 2016

(30) Foreign Application Priority Data
Feb. 16, 2015 (DE) 102015102177.3

(51) Int. Cl. G01R 31/36

(52) U.S. Cl. CPC G01R 31/362

(57) ABSTRACT

A method for determining a state of charge of a rechargeable battery using an open-circuit voltage characteristic curve of the rechargeable battery includes the steps of (a) loading the rechargeable battery in any desired manner by an application up to a first time; discharging the rechargeable battery with a prespecified discharge current from the first time up to a second time; discharging the rechargeable battery at most with a quiescent current, which is produced by the application, from the second time up to a third time; measuring an open-circuit voltage of the rechargeable battery at the earliest at the third time; and determining the state of charge using the open-circuit voltage characteristic curve on the basis of the open-circuit voltage. Also described is a corresponding apparatus, a corresponding computer program and a corresponding storage medium.

### CROSS-REFERENCE TO RELATED APPLICATION

This application claims priority to German Patent Application No. DE 10 2015 102 177.3, filed Feb. 16, 2015, which is incorporated by reference herein in its entirety.

### FIELD OF THE INVENTION

The present invention relates to a method for determining the state of charge of a rechargeable battery by means of an open-circuit voltage characteristic curve of the rechargeable battery. The present invention furthermore relates to a corresponding apparatus, to a corresponding computer program and to a corresponding storage medium.

### BACKGROUND OF THE INVENTION

The prior art comprises an extremely wide variety of rechargeable batteries which are permanently incorporated in an application, for example in the form of a 12 V starter battery in a motor vehicle. For the purpose of reliable operation, it is necessary to determine the actual state of charge (SOC) of known rechargeable batteries of this kind in as accurate a manner as possible. This is difficult, particularly in the case of nickel-zinc rechargeable batteries, since the open-circuit voltage (OCV) thereof is only weakly correlated with the state of charge over wide value ranges. In addition, a very high degree of hysteresis of the corresponding characteristic curve occurs depending on whether it is preceded by a charging process or a discharge process.

Against this background, US 2012/0133369 A1, which is incorporated by reference herein, discloses a method for estimating the capacity of a vehicle battery during operation of the battery. This method involves providing a previous state of charge of the battery, a battery temperature and integrated battery current ampere-hours, and determining whether the battery contactors were closed after they had been opened and had been disconnected from a load. The method determines whether the battery was inoperative for a sufficient time period while the contactors were open, wherein the inoperative time of the battery is based on the battery temperature, and a starting battery voltage is determined from the last time step in which the battery contactors were closed before they were opened during the inoperative time of the battery. The method determines an existing state of charge of the battery from the original battery voltage and the battery temperature, and calculates the battery capacity based on the battery-integrated current ampere-hours divided by the difference between the existing state of charge of the battery and the previous state of charge of the battery.

US 2003/0214303 A1, which is incorporated by reference herein, relates to a method and to an apparatus for determining the state of charge of a lead-acid battery. The proposed method comprises the steps of a current-based state of charge being determined with factors such as, for example, current, temperature, degree of charging efficiency, parasitic losses and self-discharge being taken into consideration. The objective of this approach is to measure and/or to calculate the open-circuit voltage during and after operation in order to determine a voltage-based state of charge, while the transition behavior of the open-circuit voltage is compensated, and to take into account the voltage shift which is caused by charging events.

EP 0 225 364 B1, which is incorporated by reference herein, in turn proposes a method for monitoring the state of charge of a storage battery, said method comprising the following steps: storing reference data which represents the state of charge, measuring the battery voltage, the battery temperature and the current which flows through the battery for providing an indication of the state of charge, integrating the measuring current for providing an indication of the charging loss after measuring the battery voltage when charging means are switched on and/or significant loads are connected, and continuously estimating the available residual charge from the stored reference data and the result of the integration, wherein estimating the available residual charge comprises the following further steps: measuring the voltage and the time profile 16s of said voltage in a substantially open circuit, assigning the measured profile 16s of the residual voltage to previously stored corresponding profiles, which are measured for batteries with a known state of charge, when said substantially open state lasts for a relatively long period of time, predicting from this profile 16 the relaxation voltage, defined here, of the battery for providing the indication of the state of charge by comparing the relaxation voltage with the stored reference data and correcting the predicted relaxation voltage by each direct measurement of the relaxation voltage.

Finally, US 2006/0244458 A1, which is incorporated by reference herein, describes an implementation method for the reference value of the state of charge algorithm verification in a battery using Ah counting and OCV hysteresis.

### SUMMARY OF THE INVENTION

Described herein is a method for determining the state of charge of a rechargeable battery by means of an open-circuit voltage characteristic curve of the rechargeable battery, a corresponding apparatus, a corresponding computer program, and a corresponding storage medium according to the independent claims.

The proposed approach is based on the finding that there is a large voltage difference between open-circuit voltages which are established during a charging and discharging process, even if there is a long waiting time of approximately 1 hour before said voltages are measured. Accordingly, a hysteresis which requires the previous current loading of the rechargeable battery to be known is produced. Although the characteristic curves in question continue to approach one another over time, this lasts for a very long time, sometimes even for several hours to days. Therefore, this process is accelerated or at least a defined state of the battery which can be evaluated is established according to aspects of the invention.

One advantage of this solution is that it is largely independent of the characteristics of the charging/discharging profile which is present before the time at which the state of charge is determined. To this end, deliberate discharging ensures that the open-circuit voltage settles at a defined value which is related to a characteristic curve to be determined, and is reproducible and is independent of the preceding current loading.

### BRIEF DESCRIPTION OF THE DRAWINGS

An exemplary embodiment of the invention is illustrated in the drawings and will be described in greater detail below.

FIG. 1 shows a graphical representation of the method according to aspects of the invention.

FIG. 2 shows a set of OCV characteristic curves with different charging/discharging rates.

### DETAILED DESCRIPTION OF THE INVENTION

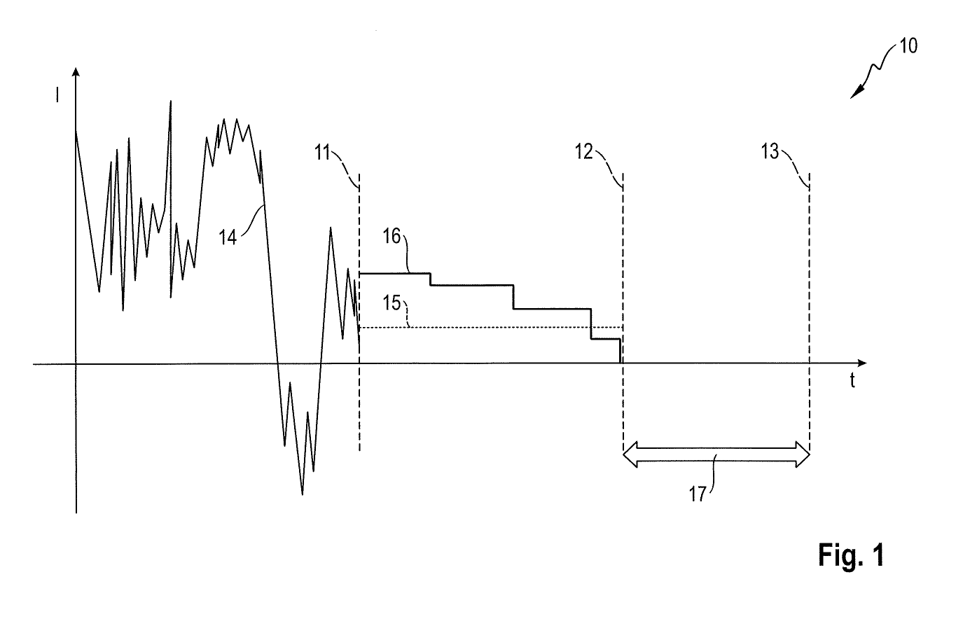

FIG. 1 illustrates the course of the method 10 according to aspects of the invention on the basis of a nickel-zinc rechargeable battery which is used as a starter battery of a vehicle which is not shown in the present figures as such for reasons of simplicity. In order to supply power to the on-board electrical system of the vehicle, the starter battery, which comprises 1.65 V cells with a nominal capacity of, for example, 40 Ah, supplies a total voltage of 12 V. Starter batteries of this generic type, for example manufactured by PowerGenix, are known to a person skilled in the art and are commercially available.

As shown in the figures, the starter battery in the application scenario under consideration is loaded in any desired manner up to a first time 11 which is marked in FIG. 1; that is to say any desired charging and discharging processes according to an unknown current profile 14 of the application take place. At the first time 11, the application is switched off and the starter battery is then discharged with a defined constant current I or current profile over a discharge time period of a few minutes, for example between 1 minute and 5 minutes, wherein a second time 12 marks the end of the discharge time period according to the figures. In this case, the discharge current I has a prespecified intensity 15 or a prespecified profile 16 over the discharge time period. To this end, it is possible, for example, for defined current consumers to be connected and disconnected again. Said consumers may include, for example, a rear windshield heater and a seat heater of the vehicle.

At the second time 12, discharging is terminated or the current I is reduced to a much lower residual value, for example 40 mA, which may possibly continuously flow in the target application as quiescent current in any case. In this way, the starter battery is discharged at most with said quiescent current, which is produced by the application, I≅40 mA over a relaxation time period 17 of, for example, 1 hour, so that the open-circuit voltage settles to a sufficient extent. The open-circuit voltage of the starter battery is measured only at a third time 13 which defines the end of the relaxation time period 17.

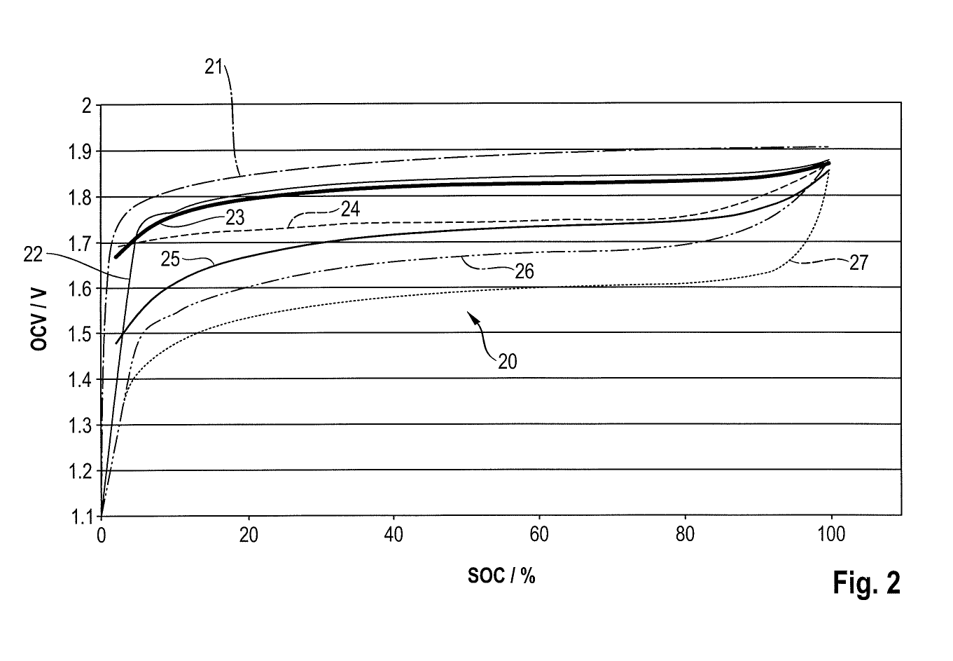

Finally, the state of charge is determined by means of an adjusted open-circuit voltage characteristic curve on the basis of the open-circuit voltage. It should be noted here that different voltages can be established depending on whether and with which current I the battery has already been charged or discharged, even though the state of charge should theoretically be the same on the basis of the Ah counting. The set of OCV characteristic curves 20 according to FIG. 2 illustrates this property.

In this respect, FIG. 2 illustrates a plurality of charging/discharging characteristic curves 21, 22, 23, 24, 25, 26, 27 of an individual cell of the starter battery. In this case, a first open-circuit voltage characteristic curve 21 is established after full and abrupt charging of the starter battery with a current corresponding to 1C, whereas a second open-circuit voltage characteristic curve 22 results when the starter battery has been charged with a current corresponding to C/20, wherein C represents the nominal capacity of the starter battery in Ah in each case.

A third open-circuit voltage characteristic curve 23 is created in a method known as the voltage relaxation method (VRM) by the starter battery or individual cell initially being fully discharged down to a state of charge of 0%. Said battery or cell is then charged in intervals which are as constant as possible, for example in steps of 5% of the nominal capacity, that is to say the respective current is increased in accordance with each step. Each step is followed by a certain waiting time, for example of 1 hour, until the battery or cell voltage has stabilized. This time is also called the relaxation time. The open-circuit voltage OCV is then measured. The process is continued until a state of charge of 100% is achieved. In this method, the state of charge is preferably ascertained by precise Ah counting.

A fourth open-circuit voltage characteristic curve 24 corresponds to a manufacturer-specific average loading profile of the starter battery. In order to create the fifth open-circuit voltage characteristic curve 25, the procedure described above for the third open-circuit voltage characteristic curve 23 is followed in the reverse direction by stepwise discharging starting from a fully charged starter battery. In the case of the voltage relaxation method which forms the basis for the third open-circuit voltage characteristic curve 23 and the fifth open-circuit voltage characteristic curve 25 in FIG. 2, the relaxation time is 1 hour and the charge or discharge current is 2 A.

A sixth open-circuit voltage characteristic curve 26 results when the starter battery has been charged with a current corresponding to C/20, once again with C being the rated capacity of the starter battery in Ah, while a seventh open-circuit voltage characteristic curve 27 is established after full and abrupt discharging of the starter battery with a current corresponding to 1C.

The fifth open-circuit voltage characteristic curve 25—which represents the VRM discharge curve—has proven particularly suitable for determining the state of charge since relaxation times have already been complied with in this case.

What is claimed is:

1. A method for determining a state of charge of a rechargeable battery using an open-circuit voltage characteristic curve of the rechargeable battery, the method comprising:
loading the rechargeable battery in any desired manner by an application up to a first time,
discharging the rechargeable battery with a predetermined discharge current from the first time up to a second time,
discharging the rechargeable battery at most with a quiescent current, which is produced by the application, from the second time up to a third time,
measuring an open-circuit voltage of the rechargeable battery at the earliest at the third time, and
determining the state of charge using the open-circuit voltage characteristic curve on the basis of the open-circuit voltage.

2. The method as claimed in claim 1,
wherein the rechargeable battery is a nickel-zinc rechargeable battery.

3. The method as claimed in claim 1,
wherein the rechargeable battery is a starter battery of a vehicle, and the application comprises an on-board electrical system of the vehicle.

4. The method as claimed in claim 1,
wherein there is a discharge time period of more than one minute between the first time and the second time.

5. The method as claimed in claim 4,
wherein the discharge current has a profile which is predetermined over the discharge time period.

6. The method as claimed in claim 4,
wherein the discharge current has an intensity which is constant over the discharge time period.

7. The method as claimed in claim 1
wherein there is a relaxation time period of at least 1 hour between the second time and the third time.

8. A computer program which is configured to carry out all of the steps of a method as claimed in claim 1.

9. A machine-readable storage medium comprising a computer program as claimed in claim 9 which is stored in said storage medium.

10. An apparatus for determining a state of charge of a rechargeable battery using an open-circuit voltage characteristic curve of the rechargeable battery, said apparatus comprising:
means for loading a rechargeable battery in any desired manner by an application up to a first time,
means for discharging the rechargeable battery with a predetermined discharge current from the first time up to a second time,
means for reducing the discharge current to at most a quiescent current, which is produced by the application, from the second time up to a third time,
means for measuring an open-circuit voltage of the rechargeable battery as early as at the third time, and
means for determining the state of charge using the open-circuit voltage characteristic curve on the basis of the open-circuit voltage.
